(19) United States
(12) Patent Application Publication
(10) Pub. No.: US 2017/0142844 A1
(43) Pub. Date: May 18, 2017

(54) Device For Plasma Coating And Method For Coating A Printed Circuit Board

(71) Applicant: Siemens Aktiengesellschaft, Muenchen (DE)

(72) Inventors: Florian Eder, Erlangen (DE); Marek Maleika, Fuerth (DE); Rudolf Zrenner, Bornheim (DE)

(73) Assignee: Siemens Aktiengesellschaft, Muenchen (DE)

(21) Appl. No.: 15/319,131

(22) PCT Filed: May 8, 2015
(86) PCT No.: PCT/EP2015/060254

§ 371 Date: Dec. 15, 2016

(30) Foreign Application Priority Data
Jun. 18, 2014 (DE) 10 2014 211 713.5

(51) Int. Cl. H05K 3/28; H01J 37/32

(52) U.S. Cl. CPC H05K 3/282; H01J 37/32715; H01J 37/3244; H01J 37/32568; H01J 37/32541; H01J 2237/332

(57) ABSTRACT

A device and method for plasma coating printed circuit boards populated with components are disclosed. A workpiece carrier that is already conventional in electronics manufacturing for holding the printed circuit boards during a plasma coating may be inserted into a sealable chamber, and a plasma coating process may be performed in the chamber, with the printed circuit boards mounted in the workpiece carrier. In this manner, process steps during loading are not only saved, but substantial costs can be avoided, e.g., with respect to the typical cleaning processes.

### CROSS-REFERENCE TO RELATED APPLICATIONS

This application is a U.S. National Stage Application of International Application No. PCT/EP2015/060254 filed May 8, 2015, which designates the United States of America, and claims priority to DE Application No. 10 2014 211 713.5 filed Jun. 18, 2014, the contents of which are hereby incorporated by reference in their entirety.

### TECHNICAL FIELD

The invention relates to a device for plasma coating, and to a method for coating a printed circuit board which is populated with components.

### BACKGROUND

When manufacturing printed circuit boards which are fitted with components, it is necessary to further coat the finished printed circuit boards with a protective coating in order to protect against environmental influences. However, coating with a protective coating is in some cases disadvantageous with respect to the coating properties of the protective coating, in particular in terms of stability.

Therefore, the question of whether coating with protective coating could be supplemented and/or replaced by plasma coating, in particular by low-pressure plasma coating, is investigated.

To date, it has only been possible to insert the finished printed circuit board into a reactor and to coat said printed circuit board in the reactor in order to carry out plasma coating. Apart from this, it is a problem to ensure the integrity of a printed circuit board at low-pressure plasma voltages of usually greater than 350 volts, for the most part voltages in the range of between 400 and 600 volts.

### SUMMARY

One embodiment provides a device comprising a workpiece carrier and comprising a chamber which can be closed in a gas-tight manner, wherein the workpiece carrier can be used in electronics manufacture and, in addition to the holding means for use during transportation of the printed circuit boards, also comprises at least one electrode and can be inserted into the chamber, wherein gas supply lines and gas discharge lines are provided to/from the chamber.

In one embodiment, the at least one electrode is detachably connected in or on the workpiece carrier, so that it is possible to fit, displace and/or remove individual electrodes.

In one embodiment, a large number of electrodes, arranged in electrode pairs, are arranged in and/or on the workpiece carrier.

In one embodiment, the at least one electrode is arranged in a flexible manner in or on the workpiece carrier.

In one embodiment, the workpiece carrier comprises at least one perforated plate on which a large number of electrodes can be fixed in any desired manner.

In one embodiment, the at least one electrode can be moved in all three directions in space.

In one embodiment, at least one electrode is a rod electrode.

In one embodiment, the chamber and the workpiece carrier are matched to one another such that as little intermediate space as possible remains between the chamber and the workpiece carrier.

In one embodiment, flow-directing grids are provided in the chamber.

In one embodiment, gas pipes and/or gas hoses are provided in the chamber, said gas pipes and/or gas hoses leading to openings in or on the workpiece carrier.

Another embodiment provides a method for plasma coating printed circuit boards, in which method the plasma coating is carried out in a workpiece carrier during manufacture.

### BRIEF DESCRIPTION OF THE DRAWING

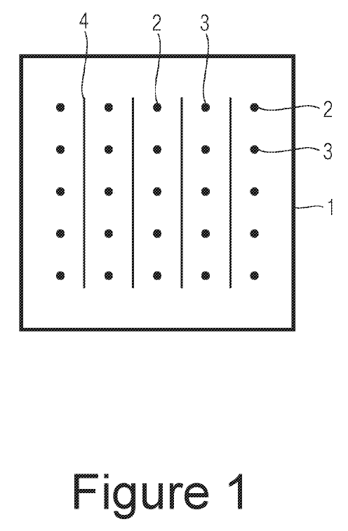

Example aspects of the invention are discussed below with reference to the sole figure, FIG. 1, which shows an example device for holding and/or coating printed circuit boards, according to one embodiment.

### DETAILED DESCRIPTION

Embodiments of the present invention provide a device for plasma coating, which device can be integrated into an electronics manufacturing process in a manner suitable for mass production. Other embodiments provide a method for plasma coating a populated printed circuit board.

Some embodiments provide a device comprising a workpiece carrier and comprising a chamber which can be closed in a gas-tight manner, wherein the workpiece carrier can be used in electronics manufacture and, in addition to the means for transporting the printed circuit boards, also comprises at least one electrode and can be inserted into the chamber, wherein gas supply lines and gas discharge lines are provided to/from the chamber. A method for plasma coating printed circuit boards, in which method the plasma coating is carried out in a workpiece carrier during manufacture, is likewise a subject matter of the invention.

By way of example, the gas supply lines and gas discharge lines are used as plasma gas feed line and gas suction-extraction line.

By way of example, flow-directing grids are provided in the chamber.

By way of example, gas pipes and/or gas hoses are provided in the chamber, said gas pipes and/or gas hoses leading to openings in or on the workpiece carrier.

A workpiece carrier and/or a cassette/transportation cassette, respectively a magazine, generally comprises, in a cube-shaped or cuboidal metal frame with insert grooves, a plate at the bottom and at the top, four metal profiles and devices for matching the metal profiles to the printed circuit boards which are respectively to be transported.

Gas flows in the chamber, for example, from one side to the other, that is to say from top to bottom or from left to right for example, in turn along the printed circuit board planes by way of example.

Secondly, a greater degree of homogeneity of the coating can be expected when gas flows from the center of the printed circuit board to the inner walls of the chamber. In the process, gas flows from the workpiece carrier to the inner walls of the chamber. This refinement has the advantage that the uniformity of the thickness of the deposited coating is optimized over the individual printed circuit boards and also over the entire loading batch.

The precursor gases are fed for this purpose, for example, centrally in the workpiece carrier or at several points close to the center. The gas is transported, for example, through thin pipelines and/or hoses to the respective openings. The counter electrode is either part of the workpiece carrier frame or the inner wall of the chamber.

The connection from the gas supply line in the chamber to the gas openings can be made by means of thin pipes or hoses, and gas routing, that is to say which gas openings of the chamber and/or in the workpiece carrier are supplied, can be changed over, for example, by a quick-action coupling.

Gas can be supplied in the chamber in a distributed manner at one or more locations at points or by flow-directing grids. The gas can then be distributed, as described above, by means of various hoses and/or pipes with corresponding distributor locations.

By way of example, these gas feed lines and/or gas suction-extraction devices are those as are used in conventional plasma generators. Gas supply or discharge lines which are used in low-pressure plasma, in particular also atmospheric plasma devices, are particularly suitable.

According to one embodiment, gas suction-extraction devices, which are integrated into the workpiece carrier and/or into the chamber and, for example, are assisted by a vacuum pump, are provided.

In principle, the workpiece carrier is a standardized, variable transportation and handling unit in electronics manufacture for a plurality of printed circuit boards and is equipped with means for stacking printed circuit boards, in particular printed circuit boards which are already populated too.

An installation manufacturer describes the manner of operation as follows:

With a standard device, such as the IPTE multi-magazine line unloader (MLU VI) for example, conventional workpiece carriers, such as the CAB and/or Miki-Plastik workpiece carrier called “magazine” here, are loaded with products from the main conveyor belt. The product (printed circuit board panel, individual printed circuit board or workpiece carrier) is stopped on the inlet belt section and pushed into a free slot of the magazine by a pusher. A move is then made to the next free slot of the magazine. The process is repeated until the magazine is completely full. The magazine is exchanged in a fully automatic manner. A magazine can be processed in the multi-magazine line unloader. There are buffer spaces for 3 empty and 2 full magazines.

The sequence in the manufacturing process can be described as follows:

A printed circuit board arrives on a main conveyor track and is stopped; the printed circuit board is pushed into a free slot of the magazine by a pusher unit; a move is made to the next free slot of the magazine; the process is repeated until the magazine is full.

Full magazines are exchanged for empty magazines in a fully automatic manner.

According to the invention, there is at least one electrode in or on the workpiece carrier. Here, an individual electrode can also form the “electrode pair”, which may be required for the plasma process and comprises electrode and ground, in the chamber of the device when the workpiece carrier frame, a part thereof and/or a wall of the chamber take on the role of a ground electrode.

However, in some embodiments a plurality of electrode pairs are arranged on the or in the workpiece carrier. In order to be suitable for geometric conditions of a printed circuit board which may be populated in a non-uniform manner, movable and/or detachable electrodes are preferably provided in or on the workpiece carrier, to provide an increased degree of flexibility with respect to positioning individual electrodes.

It has been found that it is possible to reduce the required plasma voltage in the case of an electrode pair which is situated correspondingly close to the printed circuit board which is to be coated. In particular, a reduction in this plasma voltage to values around below 300 volts, in particular below 200 volts, is possible in the case of plasma coating printed circuit boards on a workpiece carrier given an almost network-like distribution of the electrodes.

A network-like and flexible distribution of electrodes in the workpiece carrier is possible, for example, by the electrodes, preferably rod electrodes, being held in a perforated grid which is provided for them.

With a low-pressure plasma, for example at pressures of up to 8 mbar, in the range of from 0.01 to 2 mbar, is suitable in the chamber of the device.

By way of example, a stack of populated printed circuit boards, which are each mounted between at least one electrode pair, is located in the workpiece carrier, so that, when the plasma is ignited, a printed circuit board is located between at least one electrode and one counter electrode where the plasma gas is greatest and the coating is applied in the most uniform and the thickest manner.

When the coating materials are applied, attention is paid in the chamber of the device both to the frequency which is required for the plasma ignition and also the gas media flow which is necessary for the plasma deposition. Therefore, the electrode pairs are placed in or on the workpiece carrier such that the printed circuit board to be coated or the printed circuit board stack to be coated is located in an electrical field which is as uniform as possible and/or under a gas supply flow which is as uniform as possible.

In the case of coating in low-pressure plasma, location-related fluctuations in coating thickness and coating quality (or layer properties) in the chamber can be expected. This is caused firstly by the electrical alternating field not dropping uniformly and by concentration gradients of the precursor which is consumed when forming the coating, and the associated production of coating by-products.

A novel electrode concept may be advantageous to ensure a high loading density of the chamber without having to accept compromises in the coating results, in the interest of economic efficiency.

The electrodes (for example in rod form) may be arranged in layers between the printed circuit board panels to be coated and are preferably at a similar distance from one another as they are from the printed circuit boards.

One advantage of this arrangement is that the required plasma voltage can be considerably reduced, for example by a factor of 2-4. This voltage was identified as an essential characteristic variable which can lead to damage to sensitive electrical components and therefore to the destruction of the entire printed circuit board given unfavorable conditions in the coating process.

In particular, a plurality of electrode pairs may be provided in the chamber, e.g., on the workpiece carrier of the device. This has the advantage that the gas flow can be directed and the entire chamber and/or workpiece carrier are/is not coated together with the printed circuit boards. It is also possible to reduce the expenditure on cleaning the device owing to a directed gas flow in the chamber in which the plasma coating takes place.

By way of example, special gas showers are provided for the chamber. A gas shower has the task of introducing the gas, which is emitted at the end of a gas line, into the chamber in as uniform and widespread a manner as possible. In an extremely simple case, this can be performed by attaching a sintered metal filter to the line end, but it is also possible to use hoses, which generally have outlet openings, or gas distribution grid systems.

According to one embodiment of the device, the electrodes are provided in the workpiece carrier but outside the stack of printed circuit boards.

According to a further embodiment, the electrodes are located partly within the stack of printed circuit board and partly outside said stack, in or on the workpiece carrier.

The loaded workpiece carrier is inserted into the chamber of the device in order to carry out the method, wherein the electrodes are connected, for example, to plug-type contacts. In this case, it may be advantageous when the workpiece carrier and the chamber are matched to one another, so that no plasma forms between the workpiece carrier and the walls of the chamber.

Some embodiments may provide for considerably extended cleaning intervals for the coating chambers because the plasma burns substantially between the electrodes owing to the arrangement of the electrodes in or on the workpiece carrier and the chamber remains comparatively “clean” and has positive consequences for availability of the chamber.

According to one embodiment, the electrodes are detachably connected to the workpiece carrier, so that it is possible to fit, displace and/or remove individual electrodes.

Plasma coating the printed circuit boards on the workpiece carrier results in savings, in particular, with respect to loading or reloading steps too. Therefore, integration of the coating step into the existing process chain is particularly important.

With respect to cleaning, it is advantageous according to the invention that the workpiece carriers are cleaned after unloading in any case. Furthermore, it is proposed to improve the material of the workpiece carrier with respect to cleaning, possibly to replace and/or to coat it.

In this case, it is provided according to an advantageous embodiment that electrodes for generating the plasma are fastened in the and on the workpiece carrier, but such that they can be detached from said workpiece carrier, so that, for example for the cleaning step, the electrodes can be treated separately from the workpiece carrier.

According to one embodiment, the walls of the workpiece carrier are produced from a material which has a surface which is easy to clean. As an alternative or in addition to this, the surface of the workpiece carrier can also be coated with a coating which is easy to clean.

The invention will be explained in greater detail below with reference to a figure which schematically shows an exemplary embodiment:

FIG. 1 shows a plan view of an example device for holding and/or coating printed circuit boards, with the basic outline of the chamber 1 shown from above. The rod electrodes 2 and 3 are located in the chamber 1, the printed circuit boards 4 which are to be coated being arranged between said rod electrodes. The rod electrodes 2 and 3 may be of alternate polarity. Gas may flow in, for example, from bottom to top, or vice versa.

The invention relates to a device for plasma coating, and to a method for coating a printed circuit board which is populated with components. The use of workpiece carriers, which are customary in electronics manufacture in any case, for holding the printed circuit boards during plasma coating not only saves on working steps during loading but, primarily, considerable costs can be avoided with respect to the cleaning processes too.

What is claimed is:

1. A device comprising:
a chamber that is closable in a gas-tight manner,
a workpiece carrier configured to hold a plurality of printed circuit boards,
wherein the workplace carrier includes at least one electrode, and wherein the workplace carrier is configured for insertion into the chamber, and
at least one gas supply line and at least one gas discharge line coupled to the chamber for delivering gas to and from the chamber while the workplace carrier is located within the chamber.

2. The device of claim 1, wherein each electrode is detachably connected to the workpiece carrier.

3. The device of claim 1, wherein the workpiece carrier includes a plurality of electrodes arranged in electrode pairs.

4. The device of claim 1, wherein the at least one electrode is coupled to the workpiece carrier in a flexible manner.

5. The device of claim 1, wherein the workpiece carrier comprises at least one perforated plate configured to support a plurality of electrodes fixed thereto.

6. The device of claim 1, wherein each electrode is movable in x, y, and z orthogonal directions.

7. The device of claim 1, wherein at least one electrode is a rod electrode.

8. The device of claim 1, wherein the chamber and the workpiece carrier are matched to one another in size and shape to define a tight fit between the chamber and the workpiece carrier inserted in the chamber.

9. The device of claim 1, including flow-directing grids provided in the chamber.

10. The device of claim 1, including gas conduits provided in the chamber, wherein the gas conduits lead to openings in the workpiece carrier when the workpiece carrier is inserted in the chamber.

11. A method for plasma coating printed circuit boards, comprising:
inserting at least one printed circuit board in or onto a workpiece carrier, wherein the workpiece carrier includes at least one electrode;
inserting the workpiece carrier with the plurality of printed circuit boards into a chamber having at least one gas supply line and at least one gas discharge line connected thereto for delivering gas to and from the chamber;
sealing the chamber in a gas-tight manner; and
performing a plasma coating process, using the at least one gas supply line, the at least one gas discharge line, and the at least one electrode, to form a plasma coating on the at least one printed circuit board.
